(19) United States
(12) Patent Application Publication
(10) Pub. No.: US 2026/0181857 A1
(43) Pub. Date: Jun. 25, 2026

(54) APPARATUS INCLUDING MIM CAPACITORS AND CHARGE PUMP CIRCUIT

(71) Applicant: MICRON TECHNOLOGY, INC., BOISE, ID (US)

(72) Inventor: Ken OTA, Higashi Hiroshima-shi (JP)

(73) Assignee: MICRON TECHNOLOGY, INC., Boise, ID (US)

(21) Appl. No.: 19/423,847

(22) Filed: Dec. 17, 2025

Related U.S. Application Data
(60) Provisional application No. 63/736,008, filed on Dec. 19, 2024.

(51) Int. Cl. H10B 12/00; G11C 5/06; G11C 11/4063

(52) U.S. Cl. CPC H10B 12/00; G11C 5/063; G11C 11/4063

(57) ABSTRACT

Embodiments of the disclosure provides an apparatus comprising MIM capacitors of a charge pump circuit between upper and lower metal layers including first and second signal wirings orthogonal to each other. A first MIM capacitor includes first sub-MIM capacitors having their total capacitance equal to a capacitance of the first MIM capacitor. A second MIM capacitor includes second sub-MIM capacitors having their total capacitance equal to a capacitance of the second MIM capacitor. The first and second sub-MIM capacitors are arranged alternately in a checkered pattern. Along a row aligned with the first signal wiring, the first sub-MIM capacitors and the second sub-MIM capacitors have the same total length. Along a column aligned with the second signal wiring, the first sub-MIM capacitors and the second sub-MIM capacitors have the same total length. Coupling noises between the sub-MIM capacitors and the signal wirings cancel each other out.

### CROSS-REFERENCE TO RELATED APPLICATIONS

This application claims the filing benefit of U.S. Provisional Application No. 63/736,008, filed Dec. 19, 2024. This application is incorporated by reference herein in its entirety and for all purposes.

### BACKGROUND

High data reliability, high speed of memory access, low power consumption, and reduced chip size are some features that are demanded from semiconductor memory devices, such as a dynamic random-access memory (DRAM). A semiconductor memory device may include a voltage generator to generate an internal power supply voltage from an external power supply voltage. The external voltage may be supplied to a memory device from an external device. The generated internal voltage may be supplied to various circuits, components, or the like in the memory device. A memory device or its voltage generator may include a charge pump circuit to generate a higher output voltage than an input voltage. A charge pump circuit may include a capacitor that is charged during charge pump operation. The charge stored in the capacitor is used to boost an external input voltage to generate a higher internal voltage. Such boost/pump capacitor may be a metal-insulator-metal (MIM) capacitor.

### BRIEF DESCRIPTION OF THE DRAWINGS

FIG. 1 depicts an example layout of MIM capacitors of an apparatus according to some embodiments of the disclosure.

FIG. 2A is a schematic of a charge pump circuit according to some embodiments of the disclosure, and FIG. 2B is a combined diagram of a layout of corresponding MIM capacitors and a schematic of a corresponding charge pump circuit according to some embodiments of the disclosure.

FIG. 3A is a schematic of a charge pump circuit according to some embodiments of the disclosure, and FIG. 3B is a combined diagram of a layout of corresponding MIM capacitors and a schematic of a corresponding charge pump circuit according to some embodiments of the disclosure.

FIG. 4A is a schematic of a charge pump circuit according to some embodiments of the disclosure, and FIG. 4B is a combined diagram of a layout of corresponding MIM capacitors and a schematic of a corresponding charge pump circuit according to some embodiments of the disclosure.

FIG. 5A is a schematic of a charge pump circuit according to some embodiments of the disclosure, and FIG. 5B is a combined diagram of a layout of corresponding MIM capacitors and a schematic of a corresponding charge pump circuit according to some embodiments of the disclosure. FIG. 5C depicts an example layout of MIM capacitors according to some embodiments of the disclosure.

FIG. 6A is a schematic of a charge pump circuit according to some embodiments of the disclosure, and FIG. 6B is a combined diagram of a layout of corresponding MIM capacitors and a schematic of a corresponding charge pump circuit according to some embodiments of the disclosure.

FIG. 7 is a block diagram of an example semiconductor device according to some embodiments of the disclosure.

### DETAILED DESCRIPTION

Various example embodiments of the disclosure and combinations thereof will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

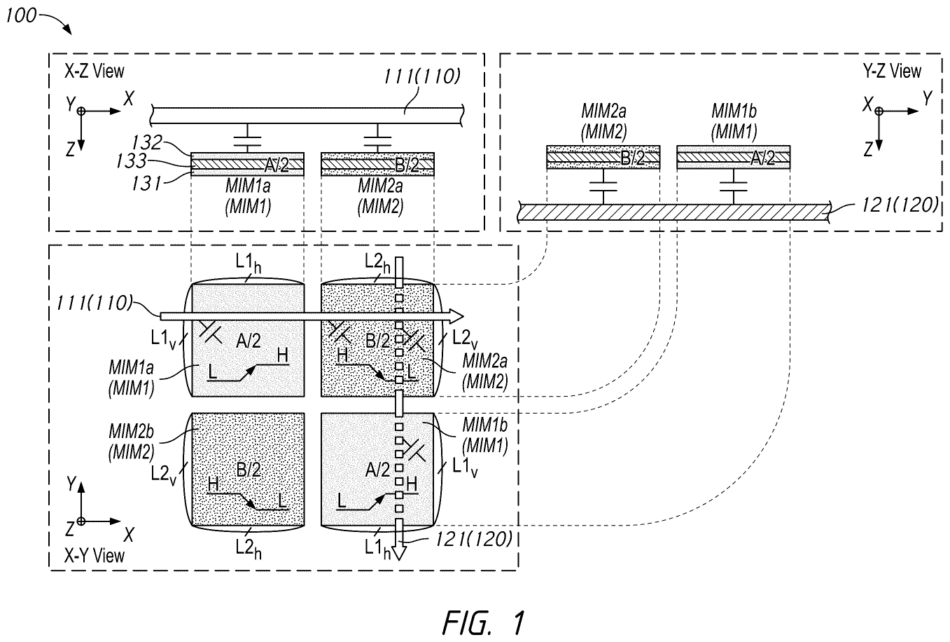

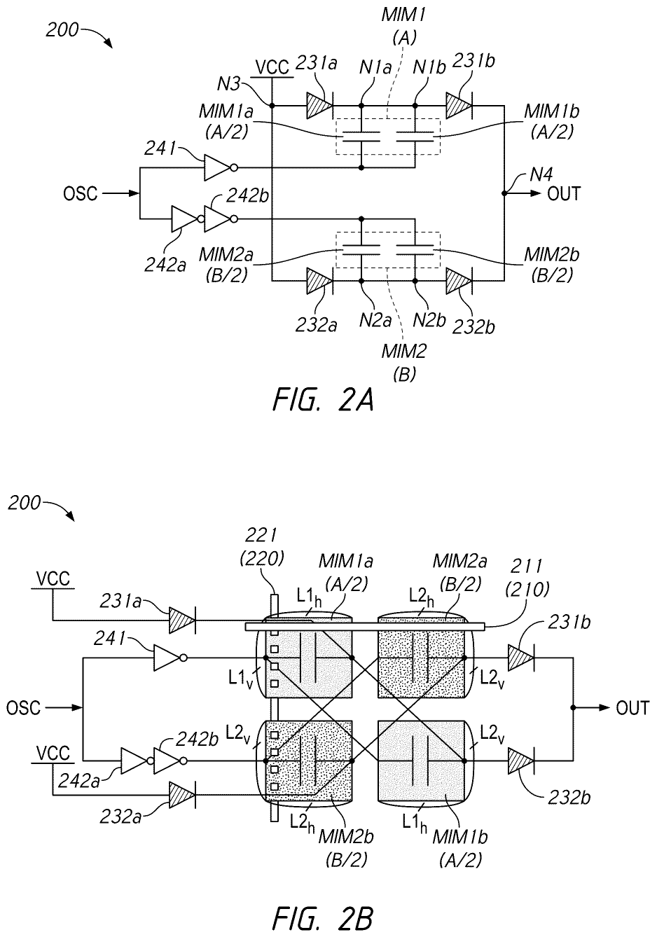

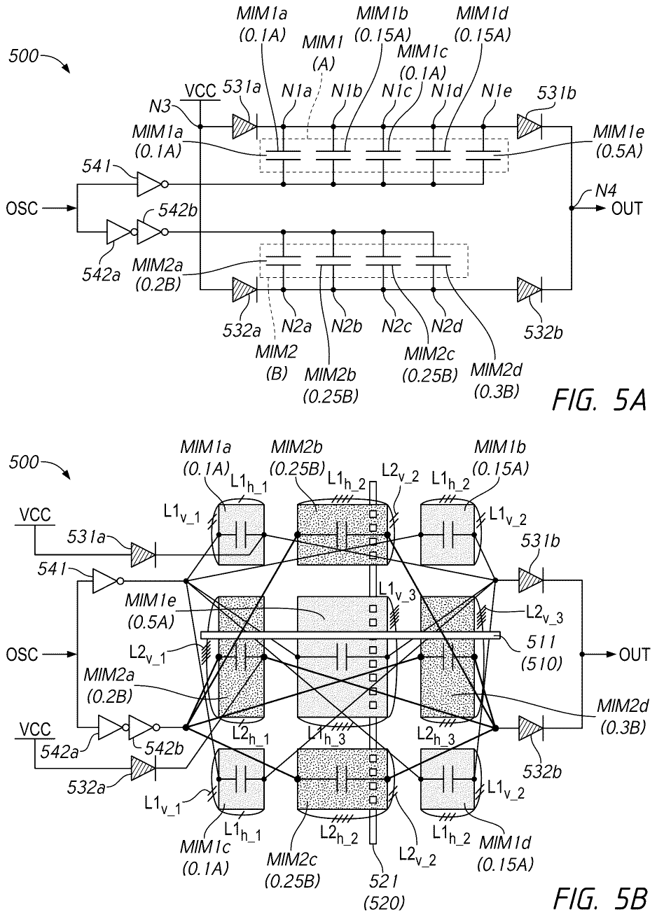

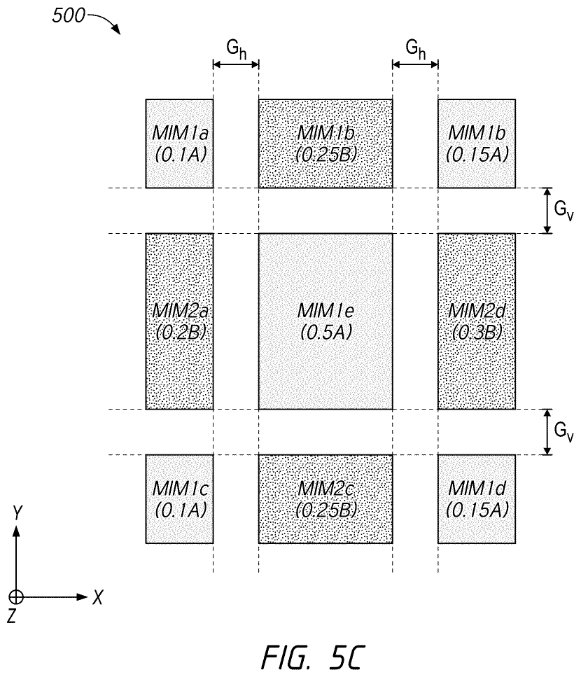

FIG. 1 depicts an example layout of MIM capacitors of an apparatus according to some embodiments of the disclosure. FIGS. 2A-6A each are a schematic of a charge pump circuit according to some embodiments of the disclosure, and FIGS. 2B-6B each are a combined diagram of a layout of corresponding MIM capacitors and a schematic of a corresponding charge pump circuit according to some embodiments of the disclosure. FIG. 5C depicts an example layout of MIM capacitors according to some embodiments of the disclosure.

An apparatus (100-600) according to some embodiments of the disclosure may be part of a semiconductor system, or part of a semiconductor memory device such as a dynamic random-access memory (DRAM). The apparatus includes a first metal layer (110-610) and a second metal layer (120-620). The second metal layer may be above or below the first metal layer. The first metal layer includes a first signal wiring (111-612). The first metal layer may include a plurality of first signal wirings. The first signal wiring(s) may extend in a first direction (e.g., an x-axis direction in the drawing, or a horizontal direction in a x-y plane). The second metal layer includes a second signal wiring (112-622). The second metal layer may include a plurality of second signal wirings. The second signal wiring(s) may extend in a second direction (e.g., a y-axis direction in the drawing, or a vertical direction in the x-y plane) orthogonal to the first direction. The signal wirings may be signal lines extending in the horizontal direction and/or the vertical direction.

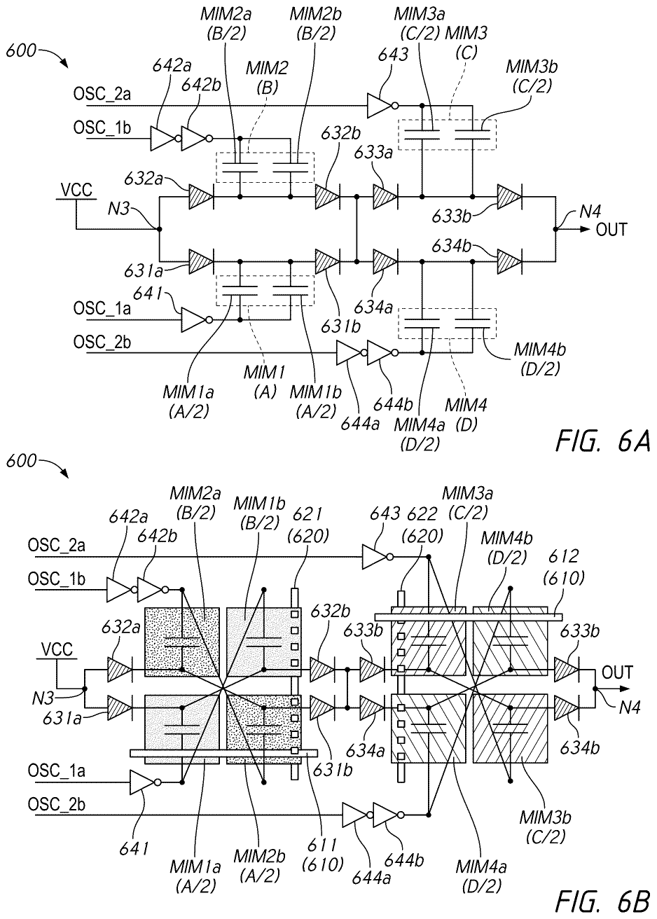

The apparatus includes two or more metal-insulator-metal (MIM) capacitors (MIM1-MIM2 in FIGS. 1-5C, or MIM1-MIM4 in FIGS. 6A-6B) between the first and second metal layers. The two or more MIM capacitors include first and second MIM capacitors (e.g., MIM1 and MIM2) adjacent to each other. The two or more MIM capacitors may further include third and fourth MIM capacitors (e.g., MIM3 and MIM4 in FIGS. 6A-6B) adjacent to each other.

The first MIM capacitor includes a plurality of first sub-MIM capacitors (e.g., MIM1a-MIM1b in FIGS. 1-4B, or MIM1a-MIM1e in FIGS. 5A-5C). The second MIM capacitor includes a plurality of second sub-MIM capacitors (e.g., MIM2a-MIM2b in FIGS. 1-4B, or MIM2a-MIM2d in FIGS. 5A-5C). The first sub-MIM capacitors and the second sub-MIM capacitors are arranged alternately in the first and second directions. The first sub-MIM capacitors and the second sub-MIM capacitors may be arranged in a checkered pattern. The sub-MIM capacitors and the sub-MIM capacitors may be in first and second diagonal arrangements, respectively, together forming a checkered pattern. As one example, in FIG. 1, MIM1a-MIM1b and MIM2a-MIM2b arranged accordingly form the checkered pattern in a plan view (e.g., an x-y plane in the drawing). As another example, in FIG. 5B, MIM1a-MIM1e and MIM2a-MIM2d arranged accordingly form the checkered pattern in a plan view. A checkered pattern may also be referred as a checkboard pattern.

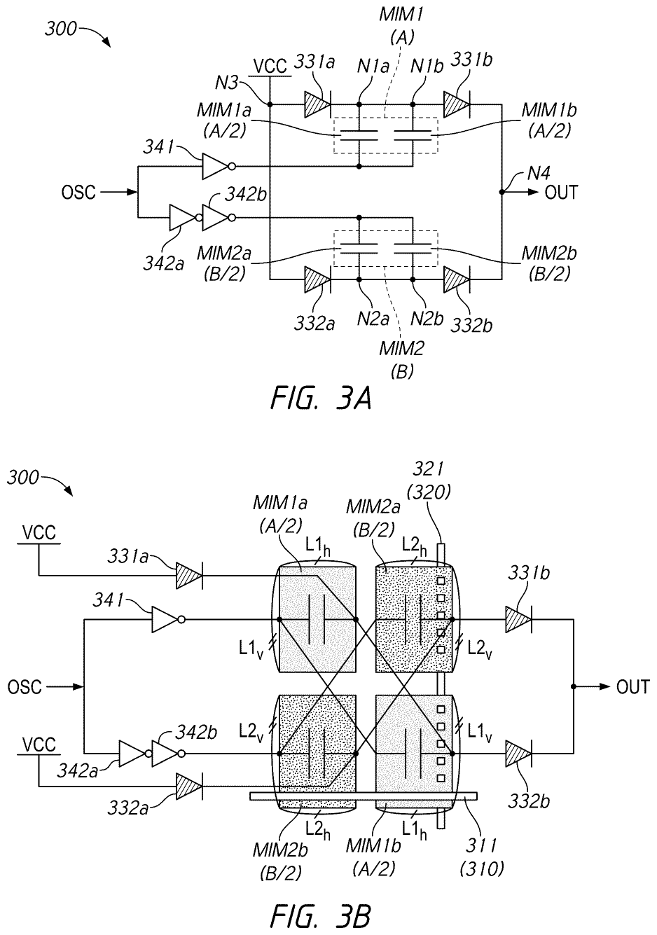

The first MIM capacitor may be divided into a plurality of first sub-MIM capacitors. The plurality of first sub-MIM capacitors may have equal capacitance with each other (e.g., FIG. 1 and FIGS. 2A-2B) or different capacitance from each other (e.g., FIGS. 3A-5C). Similarly, the second MIM capacitor may be divided into a plurality of second sub-MIM capacitors. The plurality of second sub-MIM capacitors may have equal capacitance with each other (e.g., FIG. 1 and FIGS. 2A-2B) or different capacitance from each other (e.g., FIGS. 3A-5C). The same divided capacitor arrangement may be applied to the third and fourth MIM capacitors in FIGS. 6A-6B.

Along a row aligned with one of the first and second signal wirings (e.g., 111 in FIG. 1, or 511 in FIG. 5B) in one of the first and second directions (e.g., the x-axis direction), one or more first sub-MIM capacitors (e.g., MIM1a in FIG. 1, or MIM1e in FIG. 5B) of the plurality of first sub-MIM capacitors has a first total length (e.g., L1ₕ of MIM1a in FIG. 1B, or L1_{h_3} of MIM1e in FIG. 5B). Along the same row, one or more second sub-MIM capacitors (e.g., MIM2a in FIG. 1, or MIM2a and MIM2d in FIG. 5B) of the plurality of second sub-MIM capacitors has a second total length (e.g., L2ₕ of MIM2a in FIG. 1, or L2_{h_1}+L2_{h_3} of MIM2a+MIM2d in FIG. 5B). The first total length (e.g., L1ₕ in FIG. 1, or L1_{h_3} in FIG. 5B) and the second total length (e.g., L2ₕ in FIG. 1, or L2_{h_1}+L2_{h_3} in FIG. 5B) are equal to each other.

Along a column aligned with another of the first and second wirings (e.g., 121 in FIG. 1, or 521 in FIG. 5B) in another of the first and second directions (e.g., the y-axis direction), one or more first sub-MIM capacitors (e.g., MIM1b in FIG. 1, or MIM1e in FIG. 5B) has a third total length (e.g., L1ᵥ of MIM 1b in FIG. 1, or L1_{v_3} of MIM1e in FIG. 5B). Along the same column, one or more second sub-MIM capacitors (e.g., MIM2a in FIG. 1, or MIM2b and MIM2c in FIG. 5B) of the plurality of second sub-MIM capacitors has a fourth total length (e.g., L2ᵥ of MIM2a in FIG. 1, or L2_{v_2}+L2_{v_2} of MIM2b+MIM2c in FIG. 5B). The third total length (e.g., L1ᵥ in FIG. 1, or L1_{v_3} in FIG. 5B) and the fourth total length (e.g., L2ᵥ in FIG. 1, or L2_{v_2}+L2_{v_2} in FIG. 5B) are equal to each other.

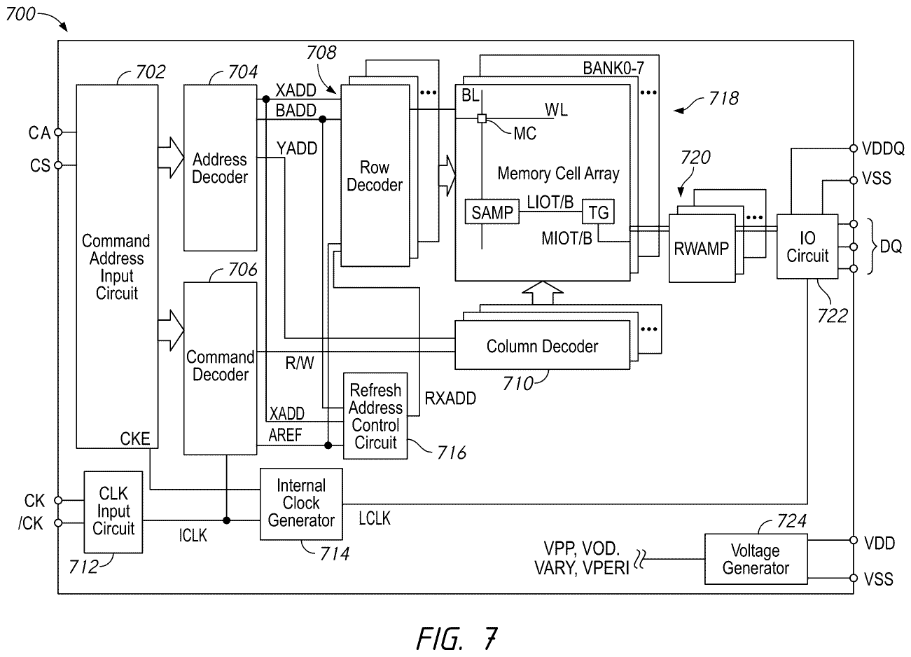

The first and second (sub-)MIM capacitors arranged as above may be included as boost/pump capacitors in a charge pump circuit (e.g., 200-600). A charge pump circuit may be included in an internal voltage generator (such as 724 in FIG. 7) of a semiconductor device. An internal voltage generator may generate various internal power supply voltages (such as VPP, VOD, VARY, and VPERI) from external power supply voltages (such as VDD and VSS). A charge pump circuit may boost an external voltage to a higher internal voltage (e.g., from VDD to VPP) by charge pumping in response to an oscillation signal. Such internal voltages may be supplied to various internal circuits, components, or the like of a semiconductor device. An oscillation signal, such as a clock signal, may be generated by an oscillator. An oscillator may be a separate circuit from or an integrated circuit of a charge pump circuit. An oscillation signal may be referred to as a pumping signal. The first and second MIM capacitors may be coupled to an oscillator. The first MIM capacitor may be supplied with a first oscillation signal. The second MIM capacitor may be supplied with a second oscillation signal. The second oscillation signal has a second phase opposite to a first phase of the first oscillation signal. The first and second oscillation signals may be 180 degrees out of phase. When the first oscillation signal supplied to the first MIM capacitor is in a High state, the second oscillation signal supplied to the second MIM capacitor is in a Low state, then the first MIM capacitor is charged. When the first oscillation signal turns Low, the second oscillation signal turns High, then the second MIM capacitor is charged. The first and second MIM capacitors are charged alternately. This operation is repeated until the desired charges are stored on the first and second MIM capacitors, which are used to boost an input voltage and generate a higher output voltage.

In some embodiments, the first sub-MIM capacitors and the second sub-MIM capacitors arranged as above may be supplied with first and second oscillation signals having opposite or reversed phases, respectively. For example, the first sub-MIM capacitors (e.g., MIM1a-MIM1b) and the second sub-MIM capacitors (e.g., MIM2a-MIM2b) may be supplied with first and second oscillation signals that are of opposite phase and alternately change from a High level to a Low level, respectively. Along a row aligned with one of the first and second signal wirings (e.g., 111 in FIG. 1) in one of the first and second directions (e.g., the x-axis/horizontal direction), when the first oscillation signal supplied to one of the first sub-MIM capacitors (e.g., MIM1a) is high, the second oscillation signal supplied to corresponding one of the second sub-MIM capacitors (e.g., MIM2a) is low. Since the lengths of the first and second sub-MIM capacitors of this pair (e.g., MIM1a and MIM2a) in the corresponding direction are equal to each other, the amount of coupling capacitance of the first sub-MIM capacitor to the aligned signal wiring and the amount of coupling capacitance of the second sub-MIM capacitor to the same aligned signal wiring are the same with each other. This means that the amount of coupling noise between the first sub-MIM capacitor and the aligned signal wiring and the amount of coupling noise between the second sub-MIM capacitor and the aligned signal wiring are equal. The frequency of the former coupling noise and that of the latter coupling noise are in opposite phase (e.g., 180 degrees out of phase), and thus the two noises cancel each other out or at least the two noises reduce each other. The same coupling noise cancellation goes for the other pair of first and second sub-MIM capacitors (e.g., MIM1b and MIM2a in FIG. 1) along a column of aligned with another of the first and second signal wiring (e.g., 121 in FIG. 1) in another of the first and second directions (e.g., the y-axis/vertical direction). Furthermore, this coupling noise cancellation or reduction is achievable with any other combinations of the first and second sub-MIM capacitors along other row and columns aligned with other first and second wirings passing above or below the first and second sub-MIM capacitors. For example, in FIG. 1, the first and second signal wirings 111 and 121 pass above and below the pair of MIM1a and MIM2a and the pair of MIM1b and MIM2a, respectively; however, for example, the first and second signal wirings 111 and 121 may pass above and below the pair of MIM1b and MIM2b and the pair of MIM1a and MIM2b, respectively, and these sub-MIM pairs can achieve the coupling noise cancellation.

Since the coupling noise is canceled, in the case of a charge pump circuit including the above MIM capacitor arrangement according to the present embodiments can effectively reduce or eliminate pumping noise to the signal wirings or the signals traveling through the wirings. In the present embodiments, signals that travel through the first and second signal wirings of the first and second metal layers in the depicted examples may not include the oscillation signals that are supplied to the MIM capacitors. The oscillation signals may be supplied to the MIM capacitors by other routes. The signals that travel the depicted wirings may be, for example, control signals, command signals, clock signals, or the like for various circuits, components, or the like of, for example, a semiconductor device. The depicted signal wirings hence may be unrelated to the pumping signals of the MIM capacitors in the case of a charge pump circuit. Therefore, in such a case, the present embodiments are effective in canceling the noise between the MIM capacitors of the charge pump circuit and the unrelated signal wirings/the unrelated signals, such as control signals for the other circuits and components than the charge pump circuit in a semiconductor memory device.

Referring to FIG. 1, in the depicted example layout according to the present embodiments, each of MIM capacitors MIM1 and MIM2 (hereinafter simply referred to as MIM1 and MIM2) includes a lower metal film 131 as a lower electrode, an upper metal film 132 as an upper electrode above the lower metal film 131, and an insulating film 133 as an insulator or a capacitance film between the lower and upper metal films 131 and 132. In some embodiments, MIM1 and MIM2 may be provided in a portion fabricated in a back-end-of-line (BEOL) process above a semiconductor substrate. MIM1 and MIM2 include two sub-MIM capacitors MIM1a and MIM1b and two sub-MIM capacitors MIM2a and MIM2b (hereinafter simply referred to as MIM1a-MIM1b and MIM2a-MIM2b), respectively. MIM1a-MIM1b and MIM2a-MIM2b are arranged alternately in x-axis and y-axis directions in a checkered pattern. For example, MIM1a and MIM1b are arranged diagonally in one diagonal direction, and MIM2a and MIM2b are arranged diagonally in another diagonal direction orthogonal to the diagonal direction of MIM1a and MIM1b. MIM1a-MIM1b and MIM2a-MIM2b arranged accordingly form the checkered pattern in the x-y plane.

Furthermore, MIM1 is divided into MIM1a and MIM1b such that a total capacitance of MIM1a and MIM1b is the same as a capacitance of MIM1. Similarly, MIM2 is divided into MIM2a and MIM2b such that a total capacitance of MIM2a and MIM2b is the same as a capacitance of MIM2. MIM1 and MIM2 have the same capacitance amount (A=B). In the example layout of FIG. 1, MIM1a and MIM1b have an equal capacitance to each other. The capacitance (A) of MIM1 is equally split into two sub-capacitances (A/2) of MIM1a and MIM1b. Likewise, the capacitance (B) of MIM2 is equally split into MIM2a and MIM2b so that each has one half (B/2) of the MIM2 capacitance. A/2=B/2 since A=B. In the depicted layout, MIM1a and MIM1b have the same square shape in plan view with the same lengths L1ₕ and L1ᵥ in the x-axis (horizontal) and y-axis (vertical) directions, respectively. MIM1a and MIM1b hence have the same area size in the x-y plane. In a similar manner, MIM2a and MIM2b have the same square shape in plan view with the same horizontal and vertical lengths L2ₕ and L2ᵥ. MIM2a and MIM2b hence have the same area size in the x-y plane.

Such MIM1a-MIM1b and MIM2a-MIM2b forming the MIM checkered pattern are provided between the first metal layer 110 and the second metal layer 120, which are upper and lower metal layers, respectively, in the depicted example. In some embodiments, the first and second metal layers 110 and 120 and MIM1a-MIM1b and MIM2a-MIM2b may be formed in a BEOL portion. The first metal layer 110 may include a first signal wiring 111 extending in the x-axis direction. The second metal layer 120 may include a second signal wiring 121 extending in the y-axis direction. The first signal wiring 111 passes above MIM1a and MIM2a in a straight line in the x-axis direction. The second signal wiring 121 passes below MIM2a and MIM1b in a straight line in the y-axis direction. The signal wirings 111 and 121 may be signal lines where various signals, such as control signals, command signals, or the like travel.

Along a row of the checkered pattern aligned with the first signal wiring 111, the total length of one or more first sub-MIM capacitors, that is L1ₕ of MIM1a in FIG. 1, is the same as the total length of one or more second sub-MIM capacitors, that is L2ₕ of MIM2a in FIG. 1. Likewise, along a column of the checkered pattern aligned with the second signal wiring 121, the total length of one or more first sub-MIM capacitors, that is L1ᵥ of MIM1b in FIG. 1, is the same as the total length of one or more second sub-MIM capacitors, that is L2ᵥ of MIM2a in FIG. 1. In other words, in the x-axis/horizontal direction, L1ₕ of MIM1a aligned with the first signal wiring 111 and L2ₕ of MIM2a aligned with the first signal wiring 111 are equal to each other under the first signal wiring 111 of the upper metal layer 110. In a similar manner, in the y-axis/vertical direction, L1ᵥ of MIM1b and L2ₕ of MIM2a both aligned with the second signal wiring 121 are equal to each other above the second signal wiring 121 of the lower metal layer 120.

MIM1a and MIM1b may be supplied with a first oscillating signal, and MIM2a and MIM2b may be supplied with a second oscillating signal which has an opposite phase to the first oscillating signal. MIM1a-MIM1b and MIM2a-MIM2b are thus reversely charged. As described above, the coupling noise between MIM1a and the first signal wiring 111 and the coupling noise between MIM2a and the first signal wiring 111 will negate each other. Similarly, the coupling noise between MIM1b and the second signal wiring 121 and the coupling noise between MIM2a and the second signal wiring 121 will negate each other. As also described above, in the present embodiments, the oscillation signals are supplied to the MIM capacitors by other routes than the wirings 111 and 121. Therefore, the pumping noise caused at the MIM capacitors is less likely to be picked up by the unrelated signal wirings 111 and 121 that pass above and below the MIM capacitors.

Referring to FIGS. 2A and 2B, MIM1 (MIM1a-MIM1b) and MIM2 (MIM2a-MIM2b) arranged as described with reference to FIG. 1 may be included in a charge pump circuit 200, which in some embodiments may be included in a voltage generator (such as 724 in FIG. 7) of a semiconductor device. The charge pump circuit 200 boosts an external voltage (such as VDD and VSS) to a higher internal voltage (such as VPP, VOD, VARY, and VPERI) by pumping MIM1 and MIM2 in response to oscillation signals generated by an oscillator. The oscillator may be a separate circuit from or an integrated circuit of the charge pump circuit 200.

The charge pump circuit 200 may include a first pair of series-coupled diodes 231a and 231b and a second pair of series-coupled diodes 232a-232b. An input terminal of a first diode 231a of the first pair and an input terminal of a first diode 232a of the second pair are coupled to an input node N3 and supplied with a positive supply voltage VCC (or, e.g., VDD in FIG. 7). In the first pair, an output terminal of the first diode 231a is coupled to an input terminal of a second diode 231b. In the second pair, an output terminal of the first diode 232a is coupled to an input terminal of a second diode 252b. Output terminals of the second diodes 251b and 252b are then coupled to an output node N4 to output a boosted voltage. The boosted voltage may be supplied as an internal voltage to internal circuits, components, or the like of a semiconductor device.

In the charge pump circuit 200, MIM1 is coupled a middle junction between the series-coupled diodes 251a and 251b. MIM2 is coupled to a middle junction between the series-coupled diodes 252a and 252b. MIM1a-MIM1b of MIM1 are coupled to respective nodes N1a and N1b between the first and second diodes 251a and 251b. MIM2a-MIM2b of MIM2 are coupled to respective nodes N2a and N2b between the first and second diodes 252a and 252b.

MIM1 and MIM2 may be coupled to an oscillator to receive oscillating signals. In the depicted example, MIM1 is coupled to the middle junction of the first diode pair 251a, 251b at one capacitor terminal on one side, and is coupled to the oscillator at another capacitor terminal on an opposite side. Similarly, MIM2 is coupled to the middle junction of the second diode pair 252a, 252b at one capacitor terminal on one side, and is coupled to the oscillator at another capacitor terminal on an opposite side. MIM1a and MIM1b of MIM1 are coupled to nodes N1a and N1b, respectively, on one side and commonly coupled to the oscillator on the other side. MIM2a and MIM2b of MIM2 are coupled to nodes N2a and N2b, respectively, on one side and commonly coupled to the oscillator on the other side. MIM1 is coupled to the oscillator via an inverter 241. MIM2 is coupled to the oscillator via series-coupled inverters 242a and 242b. Through the inverter 241, MIM1 and hence MIM1a-MIM1b are supplied with a first oscillation signal. Through the inverters 242a and 242b, MIM2 and hence MIM2a-MIM2b are supplied with a second oscillation signal. The second oscillation signal passing through the two-stage inverters 242a and 242b has a second phase opposite to a first phase of the first oscillation signal that passes the one-stage inverter 241. When the first oscillation signal through the inverter 241 is High, the second oscillation signal through the inverters 242a-242b is Low, then MIM1a-1b are charged. When the first oscillation signal turns Low, the second oscillation signal turns High, then MIM2a-MIM2b are charged. MIM1a-MIM1b and MIM2a-MIM2b are charged alternately until the desired charges are stored.

The layout of MIM1a-MIM1b and MIM2a-MIM2b arranged in the checkered pattern shown in FIG. 2B are the same as that shown in FIG. 1. MIM1a-MIM1b each are of a square shape and each have a half capacitance value (A/2) of MIM1 (A). MIM2a-MIM2b each are of a square shape and each have a half capacitance value (B/2) of MIM2 (B). MIM1a-MIM1b and MIM2a-MIM2b have the same area size (L1ₕ=L1ᵥ=L2ₕ=L2ᵥ) in the x-y plane. In FIG. 2B, a first signal wiring 211 in an upper metal layer 210 passes above MIM1a and MIM2a in the horizontal direction (i.e., the x-axis in FIG. 1; hereinafter the same). A second signal wiring 221 in a lower metal layer 220 passes below MIM1a and MIM2b in the vertical direction (i.e., the y-axis direction in FIG. 1; hereinafter the same). Similarly to the example of FIG. 1, MIM1a and MIM2a along the row aligned with the first signal wiring 211 have the same length L1ₕ=L2ₕ. MIM1a and MIM2b along the column aligned with the second signal wiring 221 have the same length L1ᵥ=L2ᵥ. Hence, the coupling noise cancellation between the corresponding MIM capacitors and the corresponding signal lines can be achieved in both horizontal and vertical directions.

In the example shown in FIGS. 3A and 3B according to the present embodiments, MIM1 (A) and MIM2 (B) are equally split into MIM1a-MIM1b (A/2) and MIM2a-MIM2b (B/2), respectively, in terms of the capacitance amount (where A=B and hence A/2=B/2), receiving the corresponding first and second oscillation signals having opposite phases in a charge pump circuit 300. MIM1a-MIM1b and MIM2a-MIM2b are arranged in the checkered pattern between upper and lower metal layers 310 and 320. Unlike FIG. 2B, however, MIM1a-MIM1b and MIM2a-MIM2b each have a rectangular shape. MIM1a-MIM1b each have L1ₕ in the horizontal direction and L1ᵥ in the vertical direction, where L1ᵥ is longer than L1ₕ. Similarly, MIM2a-MIM2b each have L2ₕ in the horizontal direction and L2ᵥ in the vertical direction, and L2ᵥ is longer than L2ₕ. L1ₕ and L2ₕ are equal to each other. L1ᵥ and L2ᵥ are equal to each other. Hence, MIM1a-MIM1b and MIM2a-MIM2b have the same area size in the x-y plane.

In FIG. 3B, a first signal wiring 311 in the upper metal layer 310 passes above MIM1b and MIM2b in the horizontal direction. A second signal wiring 321 in the lower metal layer 320 passes under MIM1b and MIM2a in the vertical direction. MIM1b and MIM2b along the row of the checkered pattern have the same length L1ₕ=L2ₕ under the firs signal line wiring 311. MIM1b and MIM2a along the column of the checkered pattern have the same length L1ᵥ=L2ᵥ above the second signal wiring 321. Hence, the coupling noise cancellation between the corresponding MIM capacitors and the corresponding signal lines can be achieved in both horizontal and vertical directions. The coupling noise cancellation is also achievable even if the horizontal and vertical signal lines overlap with MIM1a-MIM2a (another row) and MIM1a-MIM2b (another column), respectively. The charge ump circuit 300 has the same or substantially the same configuration as the charge pump circuit 200. Two pairs of diodes 331a-331b and 332a-332b, nodes N1a-N1b and N2a-N2b, input and output nodes N3-N4, and inverters 341 and 342a-342b correspond to components 231a-231b, 232a-232b, N1a-N1b, N2a-N2b, N3-N4, and 241 and 242a-242b in FIGS. 2A and 2B, respectively. The details thereof are thus omitted.

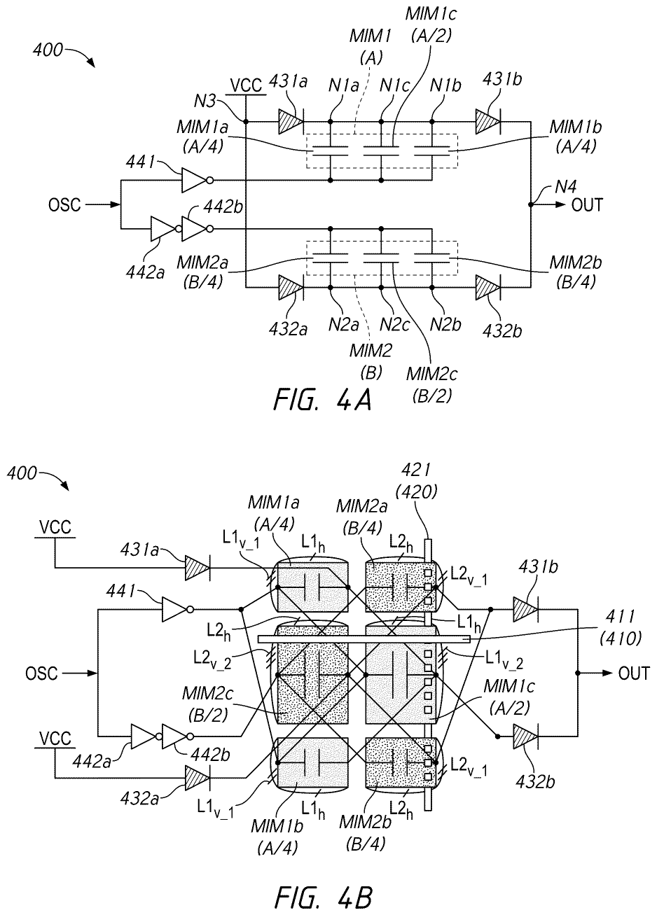

A charge pump circuit 400 in FIGS. 4A and 4B according to the present embodiments are the same or substantially the same as the charge pump circuits 200-300, except that MIM1 and MIM2 each are divided into a set of three sub-MIMs (MIM1a-MIM1c, MIM2a-MIM2c). MIM1a-MIM1c of MIM1 are coupled in parallel with each other, and are coupled to a middle junction (three respective nodes N1a-N1c) between diodes 431a and 431b of the first pair. Likewise, MIM2a-MIM2c of MIM2 are coupled in parallel with each other, and are coupled to a middle junction (three respective nodes N2a-N2c) between diodes 432a and 432b of the second pair. The diodes 431a-431b and 432a-432b as well as inverters 441 and 442a-442b and nodes N3 and N4 are the same or substantially the same as the corresponding components of the charge pump circuits 200 and 300. Furthermore, in FIGS. 4A and 4B, MIM1a-MIM1c have different capacitance from each other, and MIM2a-MIM2c have different capacitance from each other. For example, while MIM1a and MIM1b each have a quarter (A/4) of the capacitance value (A) of MIM1, MIM1c has a half (A/2) of the capacitance value (A) of MIM1. The total capacitance value (A/4+A/4+A/2) of MIM1a-MIM1c is still the same as that of MIM1. Likewise, MIM2a and MIM2b each have a quarter (B/4) of the capacitance value (B) of MIM2, and MIM1c has a half (B/2) of the capacitance value (B) of MIM2, rendering the total capacitance value (B/4+B/4+B/2) equal to that (B) of MIM2. The capacitance value of MIM1 and that of MIM2 are equal (A=B).

Referring to FIG. 4B, MIM1a and MIM1b with the A/4 capacitance each have a rectangular shape wider in the horizontal direction with horizontal length L1ₕ and vertical length L1ᵥ₋₁. MIM1c with the A/2 capacitance has a rectangular shape elongated in the vertical direction with horizontal length L1ₕ and vertical length L1ᵥ₋₂. L1ᵥ₋₂ is twice as long as L1ᵥ₋₁. MIM2a and MIM2b with the B/4 capacitance each have a rectangular shape wider in the horizontal direction with horizontal length L2ₕ and vertical length L2ᵥ₋₁. MIM2c with the B/2 capacitance has a rectangular shape elongated in the vertical direction with horizontal length L2ₕ and vertical length L2ᵥ₋₂. L2ᵥ₋₂ is twice as long as L2ᵥ₋₁. In the depicted example, L1ₕ=L2ₕ, L1_{v_1}=L2_{v_1}, and L1_{v_2}=L2_{v_2}. Furthermore, L2_{v_1}+L2_{v_2}=L1ᵥ. These length relationships keep the capacitance relationships of A/4=B/4, A/2=B/2 and A/2=B/4+B/4 where A=B.

MIM1a-MIM1c and MIM2a-MIM2c with the capacitance and length relationships as described above are still arranged in the checkered pattern between upper and lower metal layers 410 and 420. MIM1a-MIM1c and MIM2a-MIM2c are arranged alternately in both horizontal and vertical directions. MIM1a is adjacent to MIM2a in the horizontal direction, MIM1a is adjacent to MIM2c in the vertical direction, and so on. In such an arrangement, for example, if a second signal wiring 421 passes under some of MIM1a-MIM1c and some of MIM2a-MIM2c along one column of the checkered pattern (e.g., MIM1c and MIM2a-MIM2b in the depicted example), coupling noise between MIM1c and the wiring 421 and coupling noise between MIM2a-MIM2b and the wiring 421 will cancel each other out since MIM1c and MIM2a-MIM2b are charged in response to the first oscillation signal and the second oscillation signal, respectively, both signal having opposite phases. For example, when the first oscillation signal supplied to MIM1c is in a High state, the second oscillation signal supplied to MIM2a and MIM2b is in a Low state. Since the total length L2_{v_1}+L2_{v_1} of MIM2a and MIM2b is equal to L1_{v_2} of MIM1c, the total coupling capacitance between MIM2a-MIM2b and the wiring 421 has the same value as the coupling capacitance between MIM1c and the wiring 421. This means that the amount of coupling noise between MIM2a-MIM2b and the wiring 421 and the amount of coupling noise between MIM1c and the wiring 421 are equal but in opposite phase. The former coupling noise and the latter coupling noise thus negate each other. In a similar manner, if a first signal wiring 411 passes above some of MIM1a-MIM1c and some of MIM2a-MIM2c along one row of the checkered pattern (e.g., MIM1c and MIM2c in the depicted example), because of the equal length (e.g., L1ₕ and L2ₕ) and the opposite phase oscillation signals, the coupling noise cancellation will be achieved with respect to those sub-MIM capacitors and the wiring 411.

In the example depicted in FIGS. 5A-5C, while a charge pump circuit 500 includes two pairs of diodes 531a-531b and 532a-532b, MIM1 (A) and MIM2 (B, where A=B) are divided into different numbers of sub-MIM capacitors. In depicted example, MIM1 is divided into five sub-MIM capacitors, MIM1a-MIM1e, whereas MIM2 is divided into four sub-MIM capacitors, MIM2a-MIM2d. The sub-MIM1 capacitors and the sub-MIM2 capacitors are asymmetrical. MIM1a-MIM1e are coupled in parallel with each other, and are coupled to a middle junction (five respective nodes N1a-N1e) between the diodes 531a and 531b of the first pair. MIM2a-MIM2d are coupled in parallel with each other, and are coupled to a middle junction (four respective nodes N2a-N2d) between the diodes 532a and 532b of the second pair. Furthermore, the capacitance of each of MIM1 and MIM2 is split into different values for the respective sub-MIM capacitors. In the depicted example, MIM1a and MIM1c each have 0.1 A, MIM1b and MIM1d each have 0.15 A, and MIM1e has 0.5 A. MIM2a has 0.2 B, MIM2b and MIM2c each have 0.25 B, and MIM2d has 0.3 B. The number of divided sub-MIM capacitors and the capacitance amount of each sub-MIM capacitors are not limited to the depicted example, and can be arbitrarily determined based on device designs, specifications, or the like. The sub-MIM capacitors of MIM1 and the sub-MIM capacitors of MIM2 are supplied with first and second oscillation signals having opposite phases through inverter 541 and inverters 542a-542b from an oscillator, respectively. When the first oscillation signal through the inverter 541 is High, the second oscillation signal through the inverters 542a-542b is Low, then MIM1a-1e are charged. When the first oscillation signal turns Low, the second oscillation signal turns High, then MIM2a-MIM2d are charged. MIM1a-MIM1d and MIM2a-MIM2d are charged alternately until the desired charges are stored. The diodes 531a-531b and 532a-532b are coupled to nodes N3 and N4 to receive an input voltage and output a boosted voltage.

Referring to FIG. 5B, MIM1a and MIM1c with the 0.1 A capacitance each have a rectangular shape longer in the vertical direction with horizontal length L1_{h_1} and vertical length L1ᵥ₋₁. MIM1b and MIM1d with the 0.15 A capacitance each have a rectangular shape longer in the vertical direction with horizontal length L1_{h_2} and vertical length L1_{v_2}. MIM1e with the 0.5 A capacitance has a rectangular shape wider and longer than any of the sub-MIM1 capacitors with horizontal length L1_{h_3} and vertical length L1ᵥ₋₃. Turning to the sub-MIM2 capacitances, MIM2a with the 0.2 B capacitance has a rectangular shape elongated in the vertical direction with horizontal length L2_{h_1} and vertical length L2ᵥ₋₁. MIM2b and MIM2c with the 0.25 B capacitance each have a rectangular shape wider in the horizontal direction with horizontal length L2_{h_2} and vertical length L2ᵥ₋₂. MIM2d with the 0.3 B capacitance has a rectangular shape elongated in the vertical direction with horizontal length L2_{h_3} and vertical length L2ᵥ₋₃. In the depicted example, with respect to MIM1a-MIM1e, in the horizontal direction, L1_{h_1}<L1_{h_2}<L1_{h_3}. In the vertical direction, L1_{v_1}=L1_{v_2} whereas L1_{v_1} and L1_{v_2}<L1_{v_3}. With respect to MIM2a-MIM2d, in the horizontal direction, L2_{h_1} <L2_{h_3} <L2_{h_2}. In the vertical direction, L2_{v_1} =L2_{v_3} whereas L2_{v_1} and L2_{v_3}>L2_{v_2}. Comparing MIM1a-MIM1e and MIM2a-MIM2d, in the horizontal direction, L1_{h_1}=L2_{h_1}, L1_{h_3}=L2_{h_2}, and L1_{h_2}=L2_{h_3}. In the vertical direction, L1_{v_1}=L1_{v_2}=L2_{v_2}, and L1_{v_3}=L2_{v_1}=L2_{v_3}. Furthermore, in the horizontal direction, from the top row to the bottom row in the drawing, L1_{h_1}+L1_{h_2}=L2_{h_2}, L2_{h_1}+L2_{h_3}=L1_{h_3}, L1_{h_1}+L1_{h_2}=L2_{h_2}. In the vertical direction, from the left column to the right column in the drawing, L1_{v_1}+L1_{v_1}=L2_{v_1}, L2_{v_2}+L2_{v_2}=L1_{v_3}, and L1_{v_2}+L1_{v_2}=L2_{v_3}. Hence, in terms of the area size in the plan view, (MIM1a=MIM1c=0.1 A)<(MIM1b=MIM1d=0.15 A)<(MIM2a=0.2 B)<(MIM2b=MIM2c=0.25 B)<(MIM2d=0.3 B)<(MIM1e=0.5 A) where A=B. These length and area size relationships maintain the capacitance relationships of A (=0.1 A+0.15 A+0.1 A+0.15 A+0.5 A)=B (=0.2 B+0.25 B+0.25 B+0.3 B).

MIM1a-MIM1e and MIM2a-MIM2d with the capacitance and length/area size relationships as described above are still arranged in the checkered pattern between upper and lower metal layers 510 and 520. MIM1a-MIM1e and MIM2a-MIM2d are arranged alternately in both horizontal and vertical directions. MIM1a, MIM2b, and MIM1b are arranged adjacent to each other and alternately in the horizontal direction, MIM1a, MIM2a and MIM1c are arranged adjacent to each other and alternately in the vertical direction, and so on. In the depicted example, MIM1a and MIM1d are positioned at opposite corners in one diagonal line, and MIM1b and MIM1c are positioned at opposite corners in another diagonal line. MIM1e is positioned at the center. MIM2a-MIM2d are positioned between the neighboring sub-MIM1 capacitors in the rows and columns. Furthermore, as illustrated in FIG. 5C, in this arrangement, gaps Gh and Gv separating the neighboring sub-MIM capacitors may have the same size with each other in both horizontal and vertical directions.

In the above sub-MIM layout, for example, if a first signal wiring 511 passes above some of MIM1a-MIM1e and some of MIM2a-MIM2d along one row of the checkered pattern (e.g., MIM1e, and MIM2a and MIM2d), coupling noise between MIM1e and the wiring 511 and coupling noise between MIM2a and MIM2d and the wiring 511 will cancel each other out since MIM1e, and MIM2a and MIM2d are charged in response to the first oscillation signal and the second oscillation signal, respectively, both signal having opposite phases. For example, when the first oscillation signal supplied to MIM1e is in a High state, the second oscillation signal supplied to MIM2a and MIM2d is in a Low state. Since the total length L2_{h_1}+L2_{h_3} of MIM2a and MIM2d is equal to L1_{h_3} of MIM1e, the total coupling capacitance between MIM2a and MIM2d and the wiring 511 has the same value as the coupling capacitance between MIM1e and the wiring 511. This means that the amount of coupling noise between MIM2a and MIM2d and the wiring 511 and the amount of coupling noise between MIM1e and the wiring 511 are equal but in opposite phase. The former coupling noise and the latter coupling noise thus negate each other. In a similar manner, if a second signal wiring 521 passes under some of MIM1a-MIM1e and some of MIM2a-MIM2d along one column of the checkered pattern (e.g., MIM1e, and MIM2b and MIM2c), because of the equal total length (e.g., L2_{v_2}+L2_{v_2}=L1_{v_3}) and the opposite phase oscillation signals, the coupling noise cancellation will be achieved with respect to those sub-MIM capacitors and the wiring 521.

In the present embodiments described above, the apparatus 100 and the charge pump circuits 200-500 each have one pair of MIM capacitors, MIM1-MIM2 as boost/pump capacitors. The number of the capacitor pair is however not limited thereto, and can be two or more for multiple-stage voltage boost. FIGS. 6A-6B show an example of a charge pump circuit 600 that includes two pairs of MIM capacitors, MIM1-MIM2 and MIM3-MIM4, for two-stage boost. The first stage including the first pair of MIM1 and MIM2 as well as the diodes 631a-631b and 632a-632b and inverters 641 and 642a-642b is the same or substantially the same as the corresponding components in FIGS. 1-2B. In some embodiments, the sub-MIM configurations of FIGS. 2A-5C are also applicable to the first stage. The second stage including the second pair of MIM3 and MIM4 as well as diodes 633a-633b and 634a-634b and inverters 643 and 644a-644b is added to the output side of the first pair. The configuration of the second stage is the same or substantially the same as that of the first stage, and they are coupled to each other through the inverters 631b and 632b on the output side of the first stage and the inverters 633a and 634a on the input side of the second stage. In some embodiments, the sub-MIM configurations of FIGS. 2A-5C are also applicable to the second stage. In the multiple-stage boost configuration, the plurality of stages may be supplied with the oscillating pump signals having different phases between the stages. For example, MIM1 and MIM2 may receive, respectively, the first and second oscillation signals (OSC_1a and OSC_1b) being 180 degrees out of phase, and MIM 3 and MIM4 may receive, respectively, the third and fourth oscillation signals (OSC_2a and OSC_2b) being 180 degrees out of phase with each other and further being, for example, 90 degrees out of phase from the first and second oscillation signals. As one example operation, when OSC_1a through the inverter 641 is High, the other oscillation signals are Low, then MIM1a-MIM1b are charged. When OSC_1a turns Low, OSC2a through the inverter 643 turns High while the other oscillation signals remain Low, then MIM3a-MIM3b are charged. When OSC_2a turns Low, OSC_1b through the inverters 642a-642b turns High while the other oscillation signals remain Low, then MIM2a-MIM2b are charged. When OSC_1b turns Low, OSC_2b turns High while the other oscillation signals remain Low, then MIM4a-MIM4b are charged. This is repeated to alternately charge MIM1a-MIM2b, MIM2a-MIM2b, MIM3a-MIM3b, and MIM4a-MIM4b until the desired charges are stored in the respective MIM capacitors.

In the multiple-stage boost configuration, each of the MIM capacitors in each of the boost phases includes two or more sub-MIM capacitors in a similar manner to those in FIGS. 1-5C. In FIGS. 6A-6B, MIM1 and MIM2 are divided into MIM1a-MIM1b and MIM2a-MIM2b, respectively, and MIM3 and MIM4 are divided into MIM3a-MIM3b and MIM4a-MIM4b, respectively. These sub-MIM capacitors in each stage is arranged in the checkered pattern between upper and lower metal layers 610 and 620, and the same or substantially the same checkered pattern arrangements in FIGS. 1-5C are applicable. As in the case with FIGS. 1-5C, the coupling noise cancellation can be achieved between the sub-MIM capacitors and signals traveling through signal wirings 611-612 and 621-622 in the upper and lower metal layers 610 and 620.

The number of MIM capacitors, the number of sub-MIM capacitors, the capacitance value of each sub-MIM capacitor, the horizontal and vertical lengths and hence the area size of each sub-MIM capacitor in the plane view, and the like are not limited to the present embodiments, and can be arbitrarily determined based on device design, specification, or the like.

FIG. 7 is a block diagram of an example semiconductor device 700 according to some embodiments of the disclosure. The semiconductor device 700 may be a semiconductor memory device, such as a dynamic random access memory (DRAM). The semiconductor device 700 includes a memory array 718. The memory array 718 is shown as including a plurality of memory banks. In the embodiment of FIG. 1, the memory array 718 is shown as including eight memory banks BANK0-BANK7. More or fewer banks may be included in the memory array 718 of other embodiments. Each memory bank includes a plurality of word lines WL, a plurality of bit lines BL, and a plurality of memory cells MC arranged at intersections of the plurality of word lines WL and the plurality of bit line BL. Selection of the word line WL is performed by a row decoder 708 and selection of the bit lines BL is performed by a column decoder 710. In the embodiment of FIG. 1, the row decoder 708 includes a respective row decoder for each memory bank and the column decoder 710 includes a respective column decoder for each memory bank. The bit lines BL are coupled to a respective sense amplifier (SAMP) of the memory array 718. Read data from the bit line BL is amplified by the sense amplifier SAMP, and transferred to read/write amplifiers (RWAMPs) 720 over complementary local data lines (LIOT/B), transfer gate (TG), and complementary main data lines (MIOT/B) which are coupled to RWAMP 720. Conversely, write data outputted from RWAMP 720 is transferred to the sense amplifier SAMP over the complementary main data lines MIOT/B, the transfer gate TG, and the complementary local data lines LIOT/B, and written in the memory cell MC coupled to the bit line BL.

The semiconductor device 700 may employ a plurality of external terminals. The external terminals may include command and address (CA) terminals coupled to a command and address bus to receive commands and addresses and a chip select (CS) signal, clock terminals to receive clocks CK and /K, data terminals DQ to provide data, and power supply terminals to receive power supply potentials VDD, VSS, and VDDQ.

The clock terminals are supplied with external clocks CK and /K that are provided to an input circuit 712. The external clocks CK and /K may be complementary. The input circuit 712 generates an internal clock ICLK based on the CK and /K clocks. The ICLK clock is provided to the command decoder 706 and to an internal clock generator 714. The internal clock generator 714 provides various internal clocks LCLK based on the ICLK clock. The LCLK clocks may be used for timing operation of various internal circuits. The internal clocks LCLK are provided to an input and output (IO) circuit 722 to time operation of circuits included in the IO circuit 722, for example, to data receivers to time the receipt of write data. In some embodiments, the internal clocks LCLK may include a read clock which is used to control the timing of read operations, and a write clock which is used to control the timing of write operations. In some embodiments, the internal clocks may be passed to the IO circuit 722. In some embodiments, the internal clocks may also be passed to internal components, such as RWAMP 720.

The CA terminals may be supplied with memory addresses. The memory addresses supplied to the CA terminals are transferred, via a command/address input circuit 702, to an address decoder 704. The address decoder 704 receives the address and supplies a decoded row address XADD to the row decoder 708 and supplies a decoded column address YADD to the column decoder 710. The address decoder 704 may also supply a decoded bank address BADD, which may indicate the bank of the memory array 718 containing the decoded row address XADD and column address YADD. The CA terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to the command decoder 706 via the command/address input circuit 702. The command decoder 706 includes circuits to decode the internal command signals to generate various internal signals and commands for performing operations. For example, the command decoder 706 may provide a row command signal to select a word line and a column command signal to select a bit line.

The semiconductor device 700 may receive an access command which is a read command. When a read command is received, and a bank address, a row address and a column address are timely supplied with an activate command and the read command, read data is read from memory cells in the memory array 718 corresponding to the row address and column address. The read command is received by the command decoder 706, which provides internal commands so that the read data from the memory cells in the memory array 718 is provided to RWAMP 720. The read data is output to outside the semiconductor device 700 from the data terminals DQ via the IO circuit 722.

The semiconductor device 700 may receive an access command which is a write command. When the write command is received, and a bank address, a row address and a column address are timely supplied with an activate command and the write command, write data is supplied through the DQ terminals to RWAMP 720. The write data supplied to the data terminals DQ is written to the memory cells in the memory array 718 corresponding to the row address and column address. The write command is received by the command decoder 706, which provides internal commands so that the write data is received by data receivers in the IO circuit 722. Write clocks may also be provided to the external clock terminals for timing the receipt of the write data by the data receivers of the IO circuit 722. The write data is supplied via the IO circuit 722 to RWAMP 720.

The semiconductor device 700 may also receive commands causing it to carry out one or more refresh operations as part of a self-refresh mode. In some embodiments, the self-refresh mode command may be externally issued to the semiconductor device 700. In some embodiments, the self-refresh mode command may be periodically generated by a component of the device. In some embodiments, when an external signal indicates a self-refresh entry command, the refresh signal AREF may also be activated.

The power supply terminals are supplied with power supply potentials VDD and VSS. The power supply potentials VDD and VSS are supplied to an internal voltage generator circuit 724. The internal voltage generator circuit 724 generates various internal potentials such as VPP, VOD, VARY, VPERI, and the like based on the power supply potentials VDD and VSS, for supplying various voltages to be used in the semiconductor device 700. The internal reference potential VPP may be used in the row decoder 708. The internal reference potentials VOD and VARY may be used in the sense amplifiers SAMP in the memory array 718. The internal reference potential VPERI may be used in peripheral circuit blocks. The internal reference potentials are not limited to those described herein and may include other potentials as appropriate. The internal voltage generating circuit 724 may also be referred to as an internal voltage generator. The internal voltage generator circuit 724 may include a charge pump circuit. A charge pump circuit, such as those illustrated in FIG. 1

The power supply terminals are also supplied with power supply potential VDDQ. The power supply potential VDDQ is supplied to the IO circuit 722. The power supply potential VDDQ may be the same potentials as the power supply potential VDD in one embodiment of the disclosure. The power supply potential VDDQ may be different potentials from the power supply potential VDD in another embodiment of the disclosure. The power supply potential VDDQ are used for the IO circuit 722 so that power supply noise generated by the IO circuit 722 does not propagate to the other circuit blocks.

DRAM is merely one example, and the embodiments and the descriptions herein are not intended to be limited to DRAM. Memory devices other than DRAM, such as a static random-access memory (SRAM), a flash memory, an erasable programmable read-only memory (EPROM), a magnetoresistive random-access memory (MRAM), and a phase-change memory, can also be applied as the apparatuses of the present embodiments. Furthermore, devices other than memory, including logic ICs, such as a microprocessor and an application-specific integrated circuit (ASIC), are also applicable as the apparatuses according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still falling within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising:
a first metal layer including a first signal wiring that extends in a first direction;
a second metal layer above or below the first metal layer, including a second signal wiring that extends in a second direction orthogonal to the first direction; and
two or more metal-insulator-metal (MIM) capacitors between the first and second metal layers, the two or more MIM capacitors including a first MIM capacitor and a second MIM capacitor adjacent to each other, wherein
the first MIM capacitor includes a plurality of first sub-MIM capacitors and the second MIM capacitor includes a plurality of second sub-MIM capacitors, the first and second sub-MIM capacitors arranged alternately in the first and second directions,
along a row aligned with one of the first and second signal wirings, a first total length of one or more first sub-MIM capacitors of the plurality of first sub-MIM capacitors is the same as a second total length of one or more second sub-MIM capacitors of the plurality of second sub-MIM capacitors, and
along a column aligned with another of the first and second signal wirings, a third total length of one or more first sub-MIM capacitors of the plurality of first sub-MIM capacitors is the same as a fourth total length of one or more second sub-MIM capacitors of the plurality of second sub-MIM capacitors.

2. The apparatus according to claim 1, wherein the first sub-MIM capacitors and the second sub-MIM capacitors are arranged to overlap with the first signal wiring and the second signal wiring.

3. The apparatus according to claim 1, wherein the first sub-MIM capacitors and the second sub-MIM capacitors form a checkered pattern.

4. The apparatus according to claim 1, wherein
a first total capacitance of the plurality of first sub-MIM capacitors is equal to a first capacitance of the first MIM capacitor, and
a second total capacitance of the plurality of second sub-MIM capacitors is equal to a second capacitance of the second MIM capacitor.

5. The apparatus according to claim 4, wherein the first capacitance of the first MIM capacitor and the second capacitance of the second MIM capacitor are equal.

6. The apparatus according to claim 4, wherein
the plurality of first sub-MIM capacitors have a same first capacitance with each other, and
the plurality of second sub-MIM capacitors have a same second capacitance with each other.

7. The apparatus according to claim 4, wherein
the plurality of first sub-MIM capacitors have a different first capacitance from each other, and
the plurality of second sub-MIM capacitors have a different second capacitance from each other.

8. The apparatus according to claim 4, wherein
the plurality of first sub-MIM capacitors have a same first length with each other in at least one of the first direction or the second direction, and
the plurality of second sub-MIM capacitors have a same second length with each other in at least one of the first direction or the second direction.

9. The apparatus according to claim 4, wherein
the plurality of first sub-MIM capacitors have a different first length from each other in at least one of the first direction or the second direction, and
the plurality of second sub-MIM capacitors have a different second length from each other in at least one of the first direction or the second direction.

10. The apparatus according to claim 1, wherein the first and second MIM capacitors are included in a charge pump circuit.

11. The apparatus according to claim 10, wherein the first and second MIM capacitors are coupled to an oscillator.

12. The apparatus according to claim 11, wherein a first oscillation signal and a second oscillation signal are supplied to the first MIM capacitor and the second MIM capacitor, respectively, the second oscillation signal having a second phase opposite to a first phase of the first oscillation signal.

13. The apparatus according to claim 12, wherein
the two or more MIM capacitors further include a third MIM capacitor and a fourth second MIM capacitor coupled to the oscillator,
a third oscillation signal and a fourth oscillation signal are supplied to the third MIM capacitor and the fourth MIM capacitor, respectively, the third oscillation signal having a third phase opposite to a fourth phase of the fourth oscillation signal, and
the first phase and the second phase are out of phase from the third phase and the fourth phase.

14. An apparatus, comprising:
a first metal layer including a first signal wiring that extends in a first direction;
a second metal layer above or below the first metal layer, including a second signal wiring that extends in a second direction orthogonal to the first direction; and
two or more metal-insulator-metal (MIM) capacitors between the first and second metal layers, the two or more MIM capacitors including a first MIM capacitor and a second MIM capacitor adjacent to each other, wherein
the first MIM capacitor includes a plurality of first sub-MIM capacitors and the second MIM capacitor includes a plurality of second sub-MIM capacitors, the first and second sub-MIM capacitors arranged alternately in the first and second directions in a checkered pattern,
the first sub-MIM capacitors have a first total capacitance equal to a first capacitance of the first MIM capacitor, the second sub-MIM capacitors have a second total capacitance equal to a second capacitance of the second MIM capacitor, and the first capacitance and the second capacitance are equal,
one or more first sub-MIM capacitors of the plurality of first sub-MIM capacitors along a row of the checkered pattern has a first total length, one or more second sub-MIM capacitors of the plurality of first sub-MIM capacitors along the row of the checkered pattern in the first direction has a second total length, and the first total length and the second total length are equal, and
one or more first sub-MIM capacitors of the plurality of first sub-MIM capacitors along a column of the checkered pattern has a third total length, one or more second sub-MIM capacitors of the plurality of second sub-MIM capacitors along the column of the checkered pattern has a fourth total length in the second direction, the third total length and the fourth total length are equal.

15. The apparatus according to claim 14, wherein
the plurality of first sub-MIM capacitors have a same first capacitance with each other or a different first capacitance from each other, and
the plurality of second sub-MIM capacitors have a same second capacitance with each other or a different second capacitance from each other.

16. The apparatus according to claim 14, wherein
the plurality of first sub-MIM capacitors have a same first length with each other or a different first length from each other in at least one of the first direction or the second direction and,
the plurality of second sub-MIM capacitors have a same second length with each other or a different second length from each other in at least one of the first direction or the second direction.

17. The apparatus according to claim 14, wherein
the first and second MIM capacitors are included in a charge pump circuit and are coupled to an oscillator, and
a first oscillation signal and a second oscillation signal are supplied to the first MIM capacitor and the second MIM capacitor from the oscillator, respectively, a first phase of the first oscillation and a second phase of the second oscillation are opposite to each other.

18. An apparatus, comprising:
a first signal line in a first metal layer, extending in a first direction;
a second signal line in a second metal layer above or below the first metal layer, the second signal line extending in a second direction orthogonal to the first direction; and
a first MIM capacitor and a second MIM capacitor of a charge pump circuit, arranged between the first metal layer and the second metal layer, wherein
the first MIM capacitor is divided into a plurality of first sub-MIM capacitors having a first total capacitance value equal to a first capacitance value of the first MIM capacitor,
a second MIM capacitor is divided into a plurality of second sub-MIM capacitors having a second total capacitance value equal to a second capacitance value of the second MIM capacitor,
the first and second sub-MIM capacitors are arranged in a first diagonal direction and a second diagonal direction orthogonal to the first diagonal direction, respectively, to form a sub-MIM checkered pattern between the first and second metal layers,
a first total length of the first sub-MIM capacitors and a second total length of the second sub-MIM capacitors are the same with each other with respect to one of the first and second signal lines, and
a third total length of the first sub-MIM capacitors and a fourth total length of the second sub-MIM capacitors are the same with each other with respect to another one of the first and second signal lines.

19. The apparatus according to claim 18, wherein the first sub-MIM capacitors and the second-MIM capacitors receive a first pumping signal and a second pumping signal from an oscillator, respectively, the first and second pumping signals having opposite phases.

20. The apparatus according to claim 19, wherein the first and second signal lines are for signals other than the first and second pumping signals.
